(19) United States
(12) Patent Application Publication
(10) Pub. No.: US 2008/0142939 A1
(43) Pub. Date: Jun. 19, 2008

(54) TOOLS STRUCTURE FOR CHIP REDISTRIBUTION AND METHOD OF THE SAME

(75) Inventors: Wen-Kun Yang, Hsin-Chu City (TW); Chun-Hui Yu, Tainan City (TW); Chih-Wei Lin, Gueiren Township (TW)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Advanced Chip Engineering Technology Inc.

(21) Appl. No.: 11/609,944

(22) Filed: Dec. 13, 2006

(51) Int. Cl. H01L 23/12; H01L 21/58

(52) U.S. Cl. 257/678; 438/113; 257/E23.003; 257/E21.505

(57) ABSTRACT

The present invention discloses a tool structure for chip redistribution and method of chip redistribution. The tool structure comprises a base substrate, a separable adhesion film formed on the base substrate, and the patterned glues placed on the separable adhesion film for fixating the dice covered by the core paste materials formed on a fixed substrate. The fixed substrate is bonding on the core paste materials and dice to form the panel wafer. The method comprises printing the pluralities of patterned glues placed on the separable adhesion film and the bonding pluralities of dice covered by the core paste materials, and then, the fixed substrate is bonding on the core paste materials and pluralities of dice. The method further comprises curing and separating the glues and the pluralities of dice with the fixed substrate, and then cleaning the residual glues on the panel wafer (pluralities of dice).

### BACKGROUND OF THE INVENTION

1. Field of the Invention

This invention relates to chip redistribution, and more particularly to tools structure for chip redistribution and method of chip redistribution, the tools structure can simplify the processes, lower the costs and cycle time.

2. Description of the Prior Art

In conventional semiconductor device fabrication processes, a number of distinct semiconductor devices, such as memory chips or microprocessors, are fabricated on a semiconductor substrate, such as a silicon wafer. After the desired structures, circuitry, and other features of each of the semiconductor devices have been fabricated upon the semiconductor substrate, the substrate is typically singularized to separate the individual semiconductor devices from one another.

The chip-scale package (CSP) has been conventionally formed by a method in which a semiconductor wafer is cut into semiconductor chips, then the semiconductor chips are mounted on a base substrate serving as a package base at predetermined positions and bonded thereto, and they are collectively sealed with a resin, thereafter the sealing resin and the base substrate are cut into pieces together at the parts between the semiconductor chips. In another conventional method, a semiconductor wafer (not being cut into semiconductor chips yet) is mounted on a base substrate and bonded thereto, then the semiconductor wafer and the base substrate are cut simultaneously, and the cut and divided semiconductor chips and package bases are sealed with a resin.

However, in the earlier conventional manufacturing method, a problem exists in that the method essentially includes a step of positioning and mounting the cut and divided semiconductor chips one by one on the base substrate. Like wise in the latter conventional manufacturing method, a problem exists in that the method essentially includes a step of sealing the cut and divided semiconductor chips and package bases one by one with a resin. Both conventional methods require a number of working processes equal to the number of semiconductor chips, which results in a disadvantage of low productivity.

Further, at present, filling the core paste is directly filled among the dice. The pluralities of dice are formed on a temporary substrate (preferably material is glass base). Core paste (preferably material is Silicone rubber base) is formed on the temporary substrate by using a stencil printing method. In general, such filling paste technique causes an overflow filling paste on the surface of the dice in printing direction and a recess filling paste on the surface of the dice in non-printing direction, respectively. The filling paste may cover the bonding pad of the die. That is to say, such filling paste process of prior art will suffer yield and reliability issues owing to poor uniformity of the filling paste on the surface of the dice. The further disadvantage of former method are higher costs and time-consuming for manufacture.

In view of the aforementioned, the present invention provides a new tool structure that improves the cycle time and reduces the manufacturing time for a wafer level package structure to overcome the above drawback.

### SUMMARY OF THE INVENTION

The present invention will descript some preferred embodiments. However, it is appreciated that the present invention can extensively perform in other embodiments except for these detailed descriptions. The scope of the present invention is not limited to these embodiments and should be accorded the following claims.

One objective of the present invention is to provide a tools structure for chip redistribution, which can not only allow lowering the manufacturing costs, but also shortening the manufacturing time, such that the present invention can improve the life time of the tools.

Another objective of the present invention is to provide a method for chip redistribution, which can improve the cycle time and simplify the manufacturing processes, and reduce the manufacturing costs.

The present invention provides a tools structure for chip redistribution, comprising a base substrate; a separable adhesive film formed on the base; and pluralities of patterned glues placed on the separable adhesive film for fixating dice covered by core paste materials formed on a fixed substrate, therefore, the structure being used for chip redistribution. The separable adhesive film includes a separable layer or a separable tape.

The present invention provides a method for chip redistribution, comprising placing alignment patterns on a base substrate; adhering the separable adhesive film formed on a base substrate; placing the pluralities of patterned glues on the separable adhesive film formed on a base substrate; bonding the pluralities of dice with active surface site stick on the pluralities of patterned glues; curing the pluralities of patterned glues; filling paste among the pluralities of dice and covering the pluralities of dice; bonding the fixed substrate on to the core paste materials with the decided thickness; vacuum heat curing the core paste materials; peeling off the separable adhesive film between the base substrate and the pluralities of patterned glues and the pluralities of dice; and cleaning the pluralities of dice fixed on the pluralities of patterned glues (to clean the patterned glues on the dice surface to confirm no glues residue on the dice surface).

The separable step includes wet separation or dry separation, and the dry separation further include de-taping step.

### BRIEF DESCRIPTION OF THE DRAWINGS

The foregoing aspects and many of the attendant advantages of this invention will become more readily appreciated as the same becomes better understood by reference to the following detailed description, taken in conjunction with the accompanying drawings, wherein:

FIG. 1 illustrates is a schematic diagram of a panel wafer after filling the core paste according to the present invention;

FIG. 2 illustrates a top view diagram of a tool structure with alignment patterns and patterned glues according to the present invention;

FIG. 3a illustrates a cross-section diagram of a tool structure with holes on each dies according to the present invention;

FIG. 3b illustrates a cross-section diagram of a tool structure without holes according to the present invention;

FIG. 4 illustrates a schematic diagram of the combination of a wafer and a tool with holes and the interaction between the combination of the wafer and the tool with holes in a solvent according to the present invention;

FIG. 5 illustrates a schematic diagram of a wet separation method according to the present invention;

FIG. 6a illustrates a schematic diagram of taping a separable film to a base substrate of the tool according to the present invention;

FIG. 6b illustrates a cross-section diagram of the tool with the separable film and patterned glues according to the present invention;

FIG. 6c illustrates a top view diagram of the tool with the separable film and patterned glues according to the present invention;

FIG. 7 illustrates a schematic diagram of a tearing step of a dry separation method according to the present invention;

FIG. 8 illustrates a schematic diagram of a de-taping step of a dry separation method according to the present invention; and

FIG. 9 illustrates a flow chart of a method of chip redistribution according to the present invention.

### DESCRIPTION OF THE PREFERRED EMBODIMENT

In the following description, numerous specific details are provided in order to give a through understanding of embodiments of the invention. Referring now to the following description wherein the description is for the purpose of illustrating the preferred embodiments of the present invention only, and not for the purpose of limiting the same. One skilled in the relevant art will recognize, however, that the invention may be practiced without one or more of the specific details, or with other methods, components, materials, etc.

In the wafer level package process, a plurality of dice can be re-distributed by a pick and place system which has a fine alignment function and high accuracy (not shown). The lapped wafer is diced to a plurality of dice, respectively. The plurality of dice of the lapped wafer may be slightly pressed and attached by using an attaching head of the pick and place arm to make the dice flipping away from the processed wafer through a die ejecting module under the processed wafer. Then, the plurality of dice can be precisely placed on the elastic material by the Y-step motor and X-step motor. The pick and place system can be referred to the U.S. patent application Ser. No. 10/842,959 entitled “Manufacturing Tool for Wafer Level Package and Method of Placing Dies” filed on May 10, 2004 and commonly assigned to the present assignee, and the contents of which are herein incorporated by reference.

Referring to FIG. 1, it is a schematic diagram of a panel wafer 10 after filling core paste materials 16 (preferably is silicone rubber base materials) according to the present invention. The panel wafer 10 means that the pluralities of dice 14 (chips) be bonded on the fixed substrate 12 and adjacent dice area be filled core paste materials 16 and keep core paste materials 16 and the dice which surface on the same position. Further, a plurality of dice 14 is bonding on a fixed base substrate 12 by using the panel bonding system. Before that, the core paste materials 16 are filled among the plurality of dice 14 by a printing method. The core paste materials 16 are filled into the non-chip area and the back site of chips, and covered the peripheral of the plurality of dice 14. The plurality of dice 14 is covered by the core paste materials 16 and the dice 14 are back-upwardly (the dice 14 with active surface site) bonded on a tool 20.

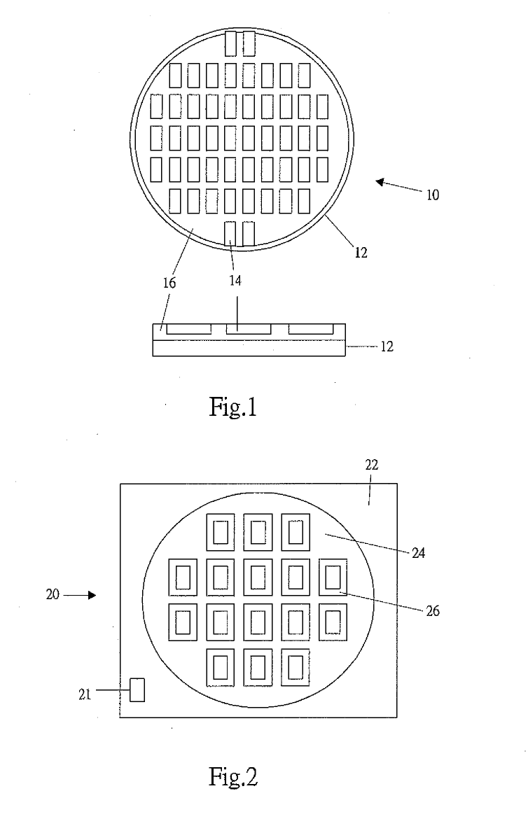

The present invention provides a tool 20 for chip re-distribution. FIG. 2 illustrates a top view diagram of a tool 20 with alignment patterns 21 according to the present invention. The tool 20 comprises a base substrate 22 with alignment pattern 21, which the alignment patterns 21 were generated by photo mask process with fine alignment during the pick and place process, a separable adhesion 24 and patterned glues 26. The plurality of patterned glues 26 is placed on the alignment patterns 21 and arranged on the separable adhesion film 24 attached on the base substrate 22. The separable adhesion film 24 is formed on the base substrate 22, and the plurality of patterned glues 26 is placed on the separable adhesion film 24 for fixating the dice 14 covered by the core paste material 16 formed on the fixed substrate 12. The present invention is used for chip redistribution. The patterned glues 26 are configured with pluralities of close loops and arranged in a matrix form on the alignment pattern. In one embodiment, the separable adhesion film 24 and the patterned glues 26 are attached to the tool 20 by a printing method. After the dice are located on the tool 20 via the patterned glue 26, then the user may perform other desired procedure, test, process on the dice.

In one embodiment, the material of fixed substrate 12 includes glass, silicon, ceramic, quartz, metal, alloy (metal) or PCB (Print Circuit Board). Further, the alloy metal is preferably composed by alloy 42 that is a nickel iron alloy whose coefficient of expansion makes it suitable for joining to silicon chips in miniature electronic circuits and consists of nickel 42%, ferrous (iron) 58%. In one embodiment, the materials of core paste materials 16 include elastic, silicone rubber, silicone resin, acrylic rubber, elastic PU (poly urethane) and porous PU. It is noted that the materials of the present invention is only used to illustrate rather than limit the present invention.

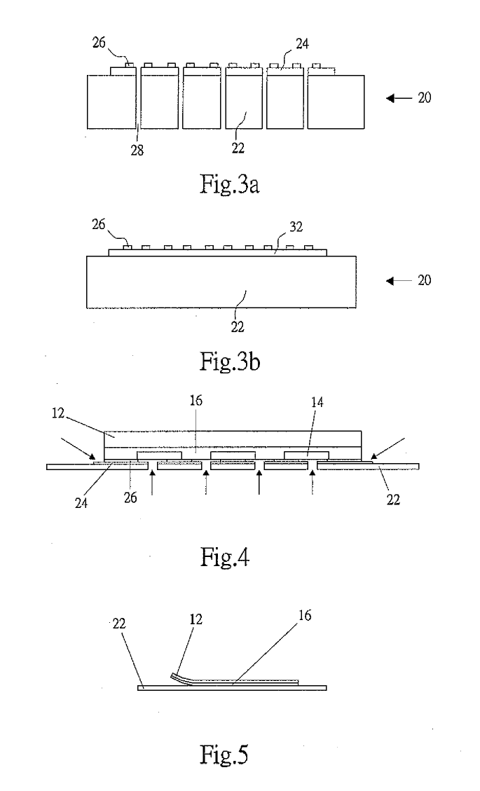

Further, the tool structure 20 of FIG. 2 is drilled by laser to form a plurality of holes 28 in each chip area (the size of holes 28 are smaller than the size of chip 14). Referring to FIG. 3a, it illustrates a cross-section diagram of a tool 20 with holes 28 on each dies according to the present invention. FIG. 3b illustrates a cross-section diagram of a tool 20 without holes according to the present invention.

According to one aspect of the present invention, the separable adhesion film 24 could be a separable layer 32 as shown in FIG. 3b.

Further, the separation is performed by a wet separation method as follows. Referring to FIG. 4, it illustrates a schematic diagram of the combination of a panel wafer 10 and a tool 20 with holes 28 and the interaction between the combination of the panel wafer 10 and the tool 20 with holes 28 in a solvent according to the present invention. The panel wafer 10 is placed on the tool 20 with holes 28, namely, the dice 14 covered by the core paste materials 16 are placed on the patterned glues 26 attached on the separable adhesion film 24. Then, the combination of the panel wafer 10 and the tool 20 is placed in a predetermined environment to perform a wet separation method. In one embodiment the predetermined environment can be the solution of DI water, glues dissolving solvent or other various solvent that can dissolve the patterned glues 26.

Moreover, the holes 28 drilled by laser allow the solvent or DI water flows to the area of the die 14 or the die fixing glues 26 and thereby increasing the interaction area between the patterned glue 26 and the solvent or DI water through the holes 28, and are indicted by the arrow shown in FIG. 4. Referring to FIG. 5, it illustrates a schematic diagram of a wet separation method according to the present invention. Then, the dice 14 attached on the fixed substrate 12 is easily separated from the base 22. Accordingly, the wet separation method is completed, and therefore, a simple separation process is provided.

The present invention also provides a tool 20 without hole as shown in FIG. 3b. Further, the structure can save the time to drill and clean the holes and lower the costs of the separable adhesion film 24. The present invention can improve the cycle time and simplify the manufacturing processes, and reduce the manufacturing costs. Consequently, the life time of the tools can be improved.

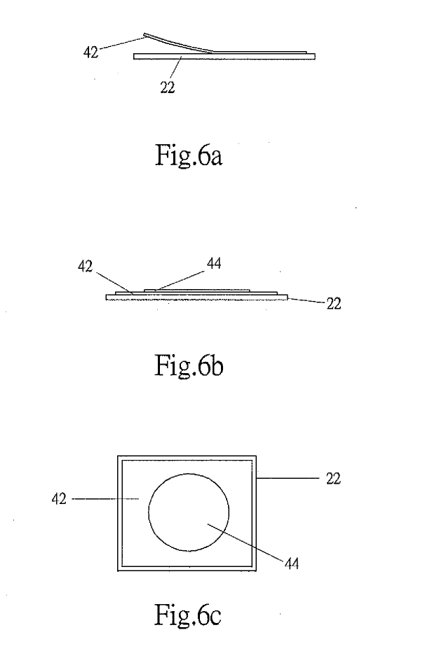

According to another aspect of the present invention, the separable adhesion film 24 could be a separable tape 42 as shown in FIG. 6a, 6b and 6c. The separation procedure is performed by a dry separation method, and the dry separation method further includes a tearing step and a de-taping step that can be seen as follows.

Referring to FIG. 6a, it illustrates a schematic diagram of taping a separable tape 42 to a base substrate 22 of the tool 20 according to the present invention. After the separable tape is taped on the base substrate 22, the patterned glues 44 are printed on the separable tape 42, as shown in FIG. 6b and 6c. FIG. 6b and 6c illustrate a cross-section diagram and a top view diagram of a tool with the separable tape 42 according to the present invention, respectively. The patterned glues 26 are used to fix the dice 14 covered by the core paste materials 16 of FIG. 1.

In one embodiment, the material of base substrate 22 includes glass, silicon, ceramic, quartz, metal, alloy or PCB (print circuit board) (preferably glass materials). The material of separable layer 24 includes composition of modify epoxy resin and silica pigment. The material of separable tape 42 includes acrylic polymer, silicone, or PET protective film. The material of patterned glues 26 include sealing glue, water soluble glue, re-workable UV glue or high melting point wax.

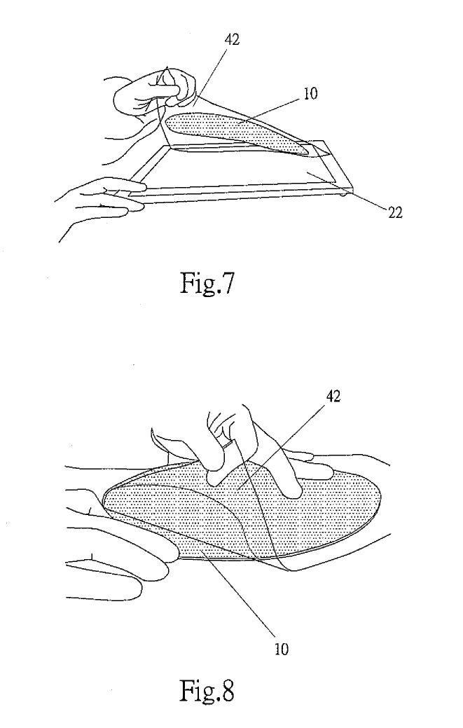

Moreover, the dry separation method according to the present invention is illustrated in FIG. 7 and 8. FIG. 7 indicates a tearing step of a dry separation method according to the present invention. The separable tape 42 is tapped on the base substrate 22 by manual or a machine (the adhesion side), and the patterned glues 26 (on non-adhesion side) are subsequently formed on the separable tape 42 by stencil printing method. Next, referring to FIG. 8, it illustrates a schematic diagram of a de-taping step of a dry separation method according to the present invention. The core paste materials 16 are divided form the edge of the fixed substrate 12 to avoid the peeling of the core paste materials 16 and the fixed substrate 12 when performing the de-taping step. Then, the separable tape 42 is separated form the dice 14 covered by the patterned glues 26. The patterned glues 26 are cleaned by a solvent after de-taping step. Accordingly, the dry separation method is completed. On the other hand, the dry separation method can omit the usage of the solvent to dissolve the patterned glues 26 for fixation of the dice 14, and can reduce the costs of printing the separable layer. Further, the dry separation method further can simplify the manufacturing process and shorten the cycle time.

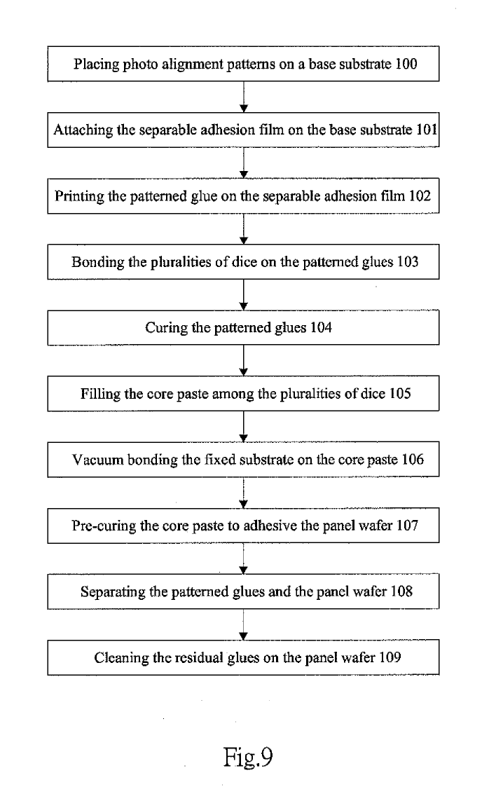

Referring to FIG. 9, it illustrates a flow chart of a method of chip redistribution according to the present invention. The present invention provides a method for chip redistribution as shown in FIG. 9. In step 100, the fine alignment patterns (formed by photo mask process) are placed on a base substrate 22. In step 101, the separable adhesion film 24 is attached on the base substrate 22. In step 102, the pluralities of patterned glues 26 are placed on the separable adhesion film 24 to form the tool 20. Then, in step 103, the pluralities of dice 14 are bonded to the tool 20 with active surface bonded to the patterned glues 26. In step 104, the patterned glues 26 and dice 14 are cured. In step 105, the core paste materials 16 are filled among the pluralities of dice 14, which are covered by the core paste materials 16. In step 106, the fixed substrate 12 is bonding on the core paste materials 16 with desired thickness. Next, in step 107, the core paste materials 16 are vacuum heat pre-curing together with the fixed substrate 12 and the tool 20.

Then, the separable adhesion film 24 with the patterned glues 26 and the pluralities of dice 14 with bonded fixed substrate 12 are separated by a dry or wet separation procedure in step 108. The clean step is performed to remove the residual glues on the die (preferably to clean the residue on the panel wafer) in step 109.

According to the aspects of the present invention, the separable adhesion film 24 can be a separable layer 32 or a separable tape 42. In one preferred embodiment, the pluralities of dice 14 with the patterned glues 26 are cured approximately at 130-170° C. for 30 min in curing step by using the tool 20 with the separable layer 32. In this application, it was due to the normal curing condition of the core paste materials 16 is 150° C. in 1 hour and the separable layer 32 can suffer the higher temperature to 170° C. without change the properties. In the separable tape embodiment, the curing temperature is approximately at 110-150° C. for 30 min. In one embodiment, the core paste materials 16 and the pluralities of dice 14 are pre-cured at 80-120° C. for 90 min in curing step before the separating step.

It is noted that the temperatures and times of the curing steps are illustrated to describe but not to limit the present invention. The temperatures and times of the curing steps can be modified according to the requirements of different materials or different conductions. Further, the separable step can be completed by a wet separation method or a dry separation method, and the dry separation method further includes a tearing step and a de-taping step.

Herein, according to the present invention, the present invention allows lowering the manufacturing costs and shortening the manufacturing time. Further, the present invention can improve the cycle time of the tools, and simplify the manufacturing processes. Therefore, the tool disclosed by the present invention can provide unexpected effect than prior art, and solve the problems of short cycle time of the tool and higher costs. The method may apply to wafer or panel industry and also can be applied and modified to other related applications. For instant, the multi-chip package and system in package also can be applied this method to do the lowest cost manufacturing process.

As will be understood by a person skilled in the art, the foregoing preferred embodiments of the present invention are illustrative of the present invention, rather than limiting the present invention. Having described the invention in connection with a preferred embodiment, modification will suggest itself to those skilled in the art. Thus, the invention is not to be limited by this embodiment. Rather, the invention is intended to cover various modifications and similar arrangements included within the spirit and scope of the appended claims, the scope of which should be accorded the broadest interpretation so as to encompass all such modifications and similar structures.

Having described the invention, the following is claimed:

1. A tools structure for chip redistribution, comprising:
a base substrate with alignment patterns;
a separable adhesion film formed on said base substrate; and
pluralities of patterned glues placed on said separable adhesion film for fixating pluralities of dice;
wherein said pluralities of dice are redistributed and attached on said pluralities of patterned glues with active surface side attached on glues, said pluralities of dice are covered by core paste materials among said adjacent dice and back side of said dice, a fixed substrate is vacuum bonding on said core paste materials and said pluralities of dice and cured to form a panel wafer.

2. The structure in claim 1, wherein said patterned glues are formed on said separable adhesion film by using a printing method.

3. The structure in claim 1, wherein said tool structure includes a plurality of holes formed within said base substrate.

4. The structure in claim 1, wherein material of said base substrate includes glass, silicon, ceramic, quartz, metal, alloy metal or PCB (print circuit board).

5. The structure in claim 1, wherein said separable adhesion film includes a separable layer or a separable tape.

6. The structure in claim 5, wherein material of said separable layer includes composition of epoxy resin or silica pigment.

7. The structure in claim 5, wherein material of said separable tape includes compositions of acrylic polymer, silicone, or polyester (PET protective film).

8. The structure in claim 1, wherein materials of said patterned glues include sealing glue, water soluble glue, re-workable UV glue or high melting point wax.

9. The structure in claim 1, wherein materials of said core paste materials include elastic, silicone rubber, silicone resin, acrylic rubber, elastic PU or porous PU.

10. The structure in claim 1, wherein materials of said fixed substrate include glass, silicon, ceramic, quartz, metal, alloy metal or PCB (print circuit board).

11. A method for chip redistribution, comprising:
placing photo alignment patterns on a base substrate;
attaching a separable adhesion film on said base substrate;
placing patterned glues on said separable adhesion film formed on said base substrate;
bonding pluralities of dice on said patterned glues;
curing said pluralities of dice and said patterned glues;
filling core paste materials among said pluralities of dice and back side of said dice;
vacuum bonding a fixed substrate on said core paste materials and said pluralities of dice on a panel wafer;
pre-curing said core paste with said fixed substrate;
separating said patterned glues and said pluralities of dice attached on said fixed substrate; and
cleaning said pluralities of dice on said panel wafer.

12. The method in claim 11, wherein said separable adhesion film includes a separable layer or a separable tape.

13. The method in claim 12, wherein said pluralities of dice are cured approximately at 130-170° C. for 30 min in said curing step when said separable adhesion film is said separable layer with said patterned glues.

14. The method in claim 12, wherein said pluralities of dice are cured approximately at 110-150° C. for 30 min in said curing step when said separable adhesion film is said separable tape with said patterned glues.

15. The method in claim 11, wherein said core paste materials and said pluralities of dice and said fixed substrate are cured at 80-120° C. for 90 min after bonding in said curing step.

16. The method in claim 11, wherein said separating step includes a wet separation method or a dry separation method.

17. The method in claim 16, wherein said wet separation method is performed by placing in a predetermined environment.

18. The method in claim 17, wherein said predetermined environment can be the solution of DI water, glues dissolving solvent or other various solvent that can dissolve said glues.

19. The method in claim 16, wherein said dry separation further includes a tearing step and a de-taping step.
